(19) United States
(12) Patent Application Publication
(10) Pub. No.: US 2010/0126763 A1
(43) Pub. Date: May 27, 2010

(54) WIRE BONDING METHOD, ELECTRONIC APPARATUS, AND METHOD OF MANUFACTURING SAME

(75) Inventors: Takayoshi Matsumura, Kawasaki (JP); Takeshi Miyakoshi, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/575,141

(22) Filed: Oct. 7, 2009

(30) Foreign Application Priority Data
Nov. 21, 2008 (JP) 2008-297446

(51) Int. Cl. H05K 1/11; H01R 43/02

(52) U.S. Cl. 174/261; 29/879

(57) ABSTRACT

A wire bonding method which includes forming a bump on a first electrode provided in a first electronic part and bonding the bump and a second electrode provided in a second electronic part by using a wire, wherein the bump and the wire are formed using materials containing Au, and an Au purity of the material forming the bump is lower than an Au purity of the material forming the wire.

### CROSS-REFERENCE TO RELATED APPLICATION

This application is based upon and claims the benefit of priority from the prior Japanese Patent Application No. 2008-297446 filed on Nov. 21, 2008, the entire contents of which are incorporated herein by reference.

### BACKGROUND

1. Field

The embodiments discussed herein are related to a wire bonding method, an electronic apparatus manufactured using the wire bonding method, and a method of manufacturing the same.

2. Description of Related Art

Hitherto, a wire bonding method is known as a method of mounting electronic parts, such as IC chips, onto a mounting substrate.

The wire bonding method is a method in which an electronic part is bonded onto a mounting substrate via a die-bonding film or the like and thereafter, an electrode pad formed in the peripheral portion of the surface of the electronic part and connection terminals on the mounting substrate are electrically connected using an Au (gold) wire or the like.

In recent years, as semiconductor integrated circuits have become finer, IC chips have rapidly decreased in size. In order to reliably supply electricity to such compact IC chips, in the wire bonding method, there has been a demand for reliably wire-connecting very small electrode pads provided on IC chips to connection terminals provided on a mounting substrate and also, preventing a short-circuit, peeling, and the like.

For example, a method disclosed in Japanese Unexamined Patent Application Publication No. 2008-235314 has been proposed as a method in the related art of manufacturing an electronic apparatus for the purpose of preventing peeling off of a wire that connects electronic parts and a mounting substrate.

### SUMMARY

According to an embodiment, a wire bonding method includes forming a bump on a first electrode provided in a first electronic part and bonding the bump and a second electrode provided in a second electronic part by using a wire, wherein the bump and the wire are formed using materials containing Au, and a Au purity of the material forming the bump is lower than a Au purity of the material forming the wire.

It is to be understood that both the foregoing summary description and the following detailed description are explanatory as to some embodiments of the present invention, and not restrictive of the present invention as claimed.

### BRIEF DESCRIPTION OF THE DRAWINGS

FIG. 1 illustrates a wire bonding apparatus;

FIG. 2 illustrates an electronic part and a mounting substrate;

FIGS. 3A to 3D illustrate a method of manufacturing an electronic apparatus according to an embodiment;

FIG. 4 illustrates an electronic apparatus according to an embodiment;

FIGS. 5A and 5B illustrate Au/Al alloy layers, which are formed in an embodiment and in the related art, respectively;

FIG. 6 illustrates a correlation between a high-temperature left-standing time period and an alloy layer diameter in a bonded area;

FIG. 7 illustrates an electronic apparatus according to another embodiment;

FIG. 8 illustrates an electronic apparatus according to another embodiment;

FIG. 9 illustrates an electronic apparatus according to another embodiment;

FIGS. 10A to 10D illustrate a method of manufacturing an electronic apparatus of the related art;

FIGS. 11A to 11C illustrate a method of manufacturing an electronic apparatus of the related art;

FIG. 12 illustrates a method of manufacturing an electronic apparatus of the related art;

FIGS. 13A to 13D illustrate a method of manufacturing an electronic apparatus of the related art; and

FIGS. 14A and 14B illustrate a wire bonding method of the related art.

### DESCRIPTION OF EXAMPLE EMBODIMENTS

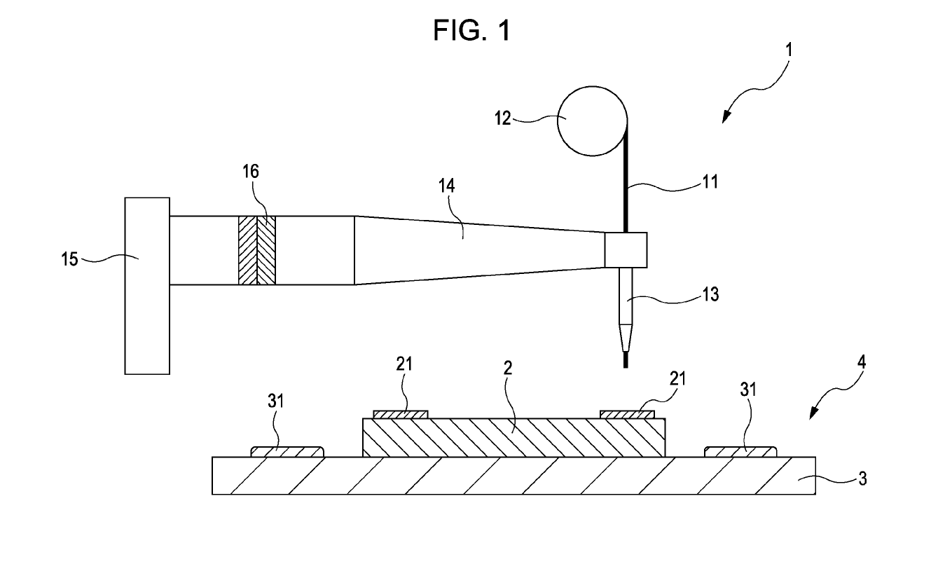

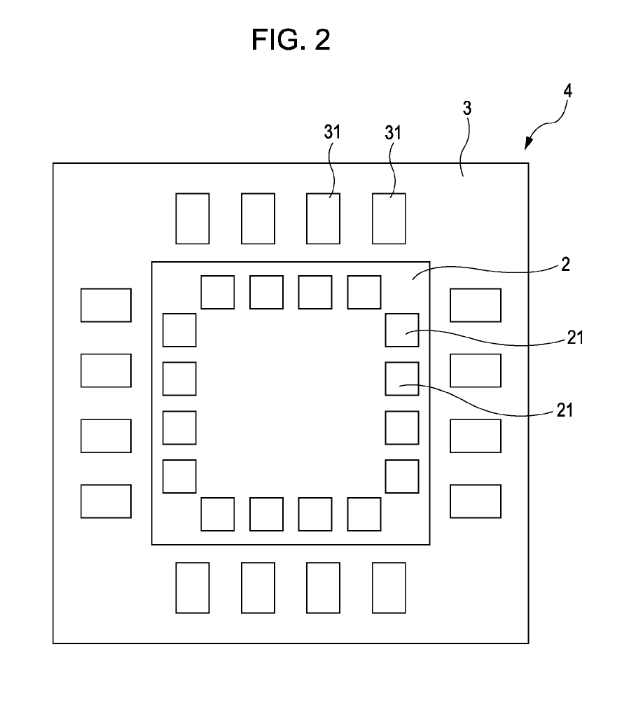

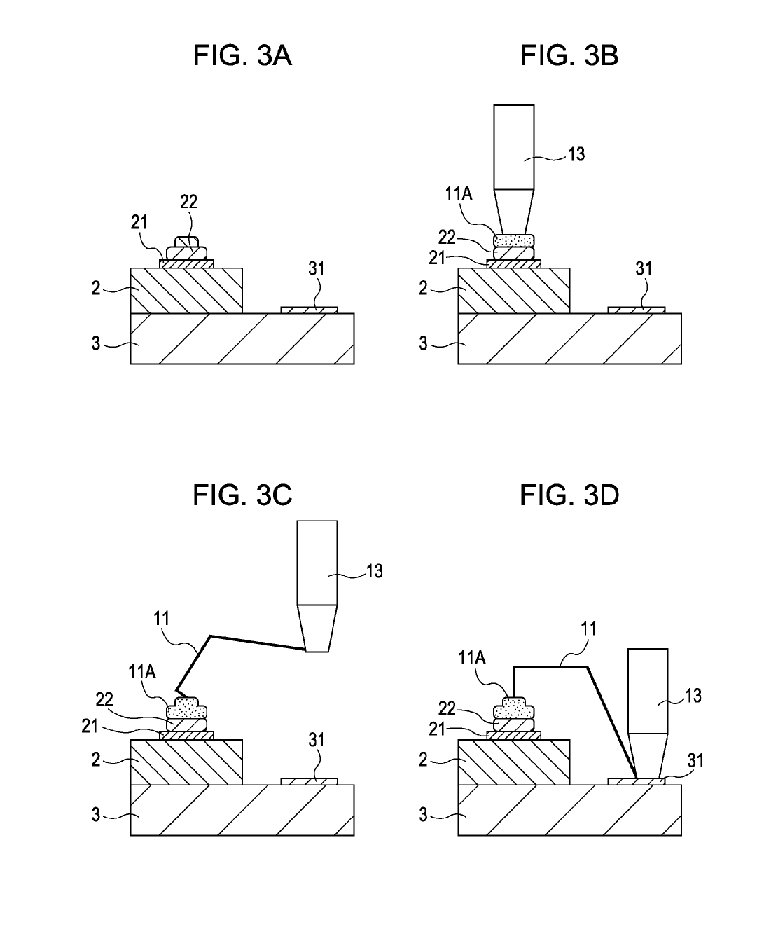

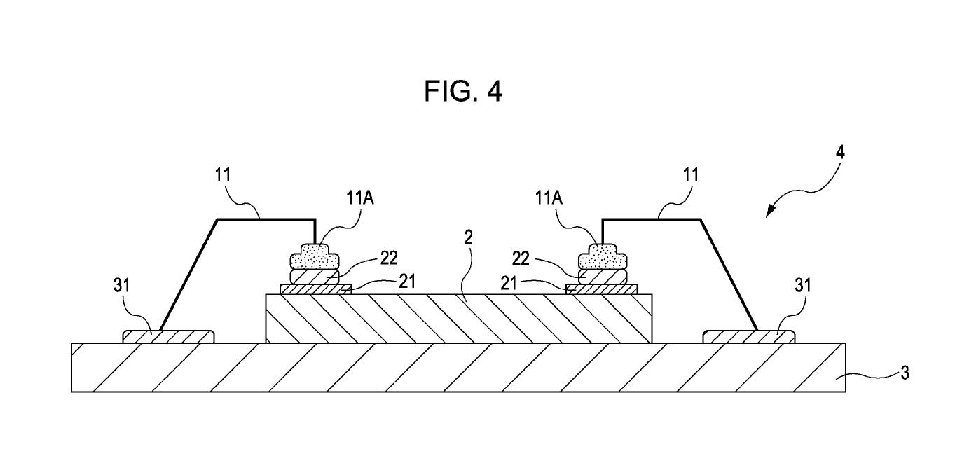

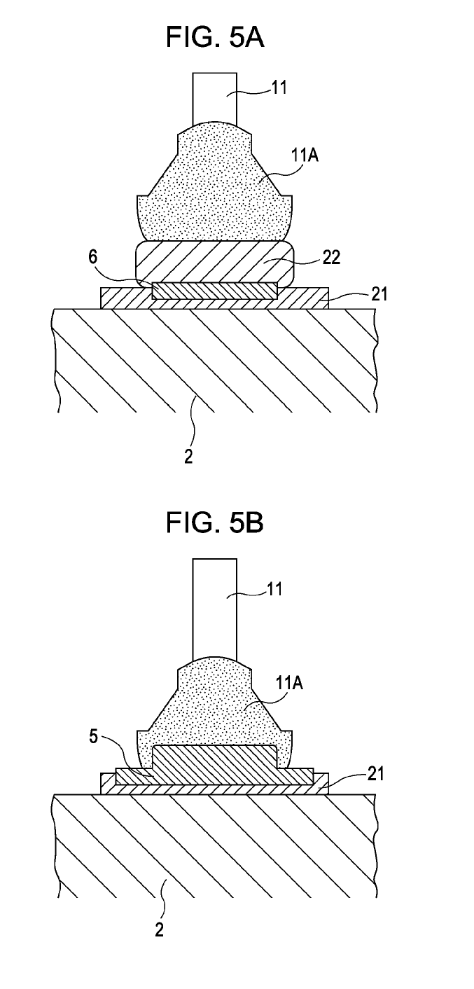

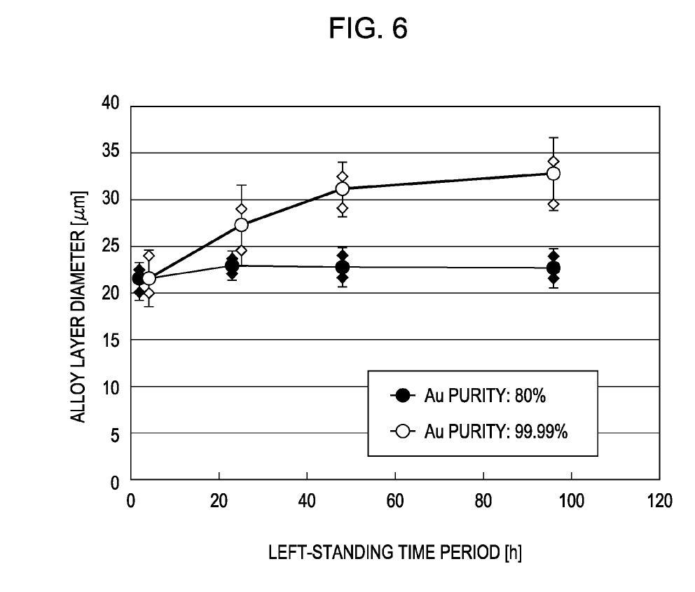

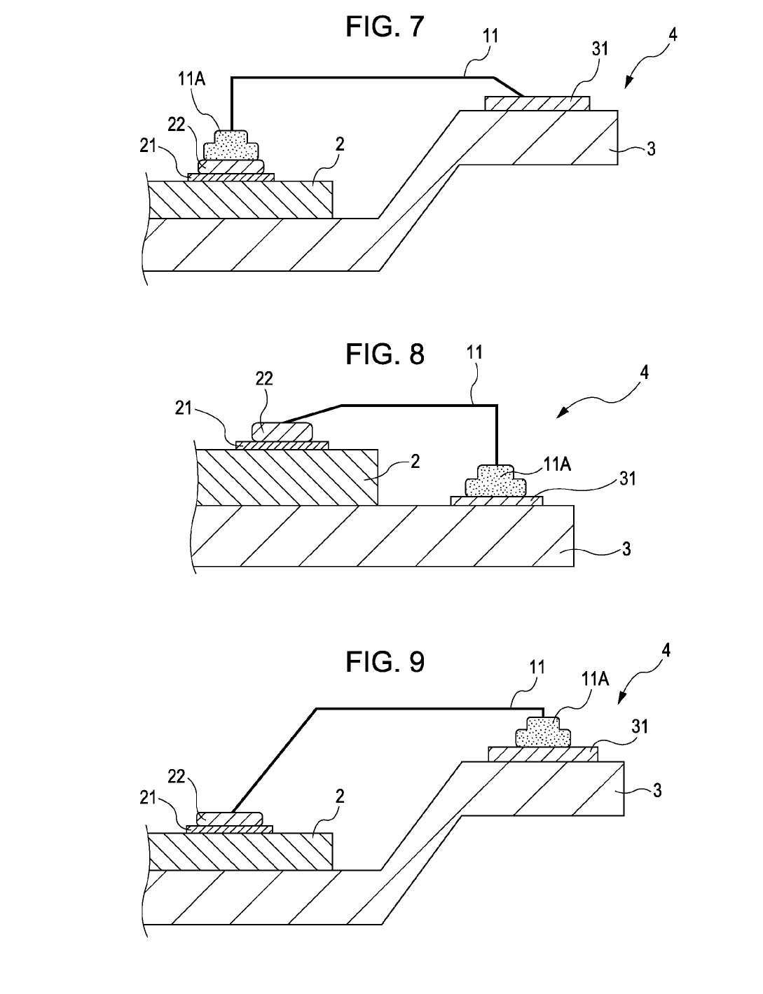

Embodiments will be described in detail below with reference to the drawings. FIG. 1 illustrates a wire bonding apparatus 1. FIG. 2 illustrates an electronic part 2 and a mounting substrate 3. FIGS. 3A to 3D illustrate a method of manufacturing an electronic apparatus according to an embodiment. FIG. 4 illustrates an electronic apparatus 4 according to an embodiment. FIG. 5A illustrates an Au/Al alloy layer 6 in an area where a first electrode 21 and a bump 22 are bonded according to an embodiment. FIG. 5B illustrates an Au/Al alloy layer 5 in an area where the first electrode 21 and a wire 11 (crimp ball 11A) are bonded according to the related art. FIG. 6 illustrates a correlation between a high-temperature left-standing time period and an alloy layer diameter in a bonded area in the Au/Al alloy layers 5 and 6. FIGS. 7 to 9 illustrate an electronic apparatus 4 according to another embodiment.

The schematic configuration of a wire bonding apparatus 1 is shown in FIG. 1. The wire bonding apparatus 1 includes a wire feeder 12 around which a wire 11 is wound, a capillary 13 that supplies the wire 11 to the electronic part 2 and the mounting substrate 3 and that applies vibration and load to the wire 11, an ultrasonic wave horn 14 that has the capillary 13 mounted at its tip end and that causes the capillary 13 to be vibrated as a result of ultrasonic waves being applied thereto, a movement mechanism 15 that moves the ultrasonic wave horn 14 in the vertical direction and in the horizontal direction and that causes the load to be generated, and a vibrator 16 that applies ultrasonic waves to the ultrasonic wave horn 14.

As a result of having the above-described configuration and the ultrasonic wave horn 14 being expanded and contracted by the vibrator 16 in the axial direction, the capillary 13 is vibrated in the axial direction of the ultrasonic wave horn 14.

Next, the configuration of the electronic part 2 and the mounting substrate 3 is shown in FIG. 2 (plan view). In the present embodiment, the electronic part 2 is an IC chip. The IC chip 2 is provided with a plurality of first electrodes 21 for making electrical connection to the mounting substrate 3. As an example, the first electrode 21 is formed using Al (aluminum).

Furthermore, the mounting substrate 3 is provided with a plurality of second electrodes (connection terminals) 31 that are connected to the plurality of corresponding first electrodes 21 of the electronic part 2. As an example, the second electrodes 31 are formed using Au (gold).

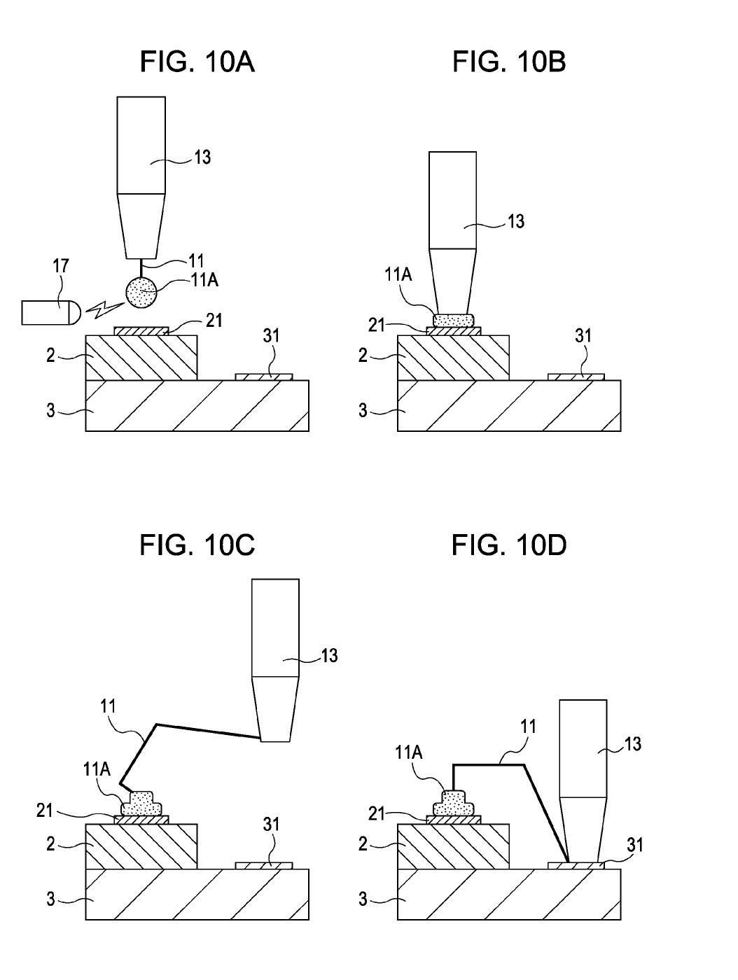

Next, a description will be given of a wire bonding method of, in the wire bonding apparatus 1, connecting (electrically bonding) the first electrodes 21 of the electronic part 2 to the second electrodes 31 of the mounting substrate 3 by using the wire 11. FIGS. 10A to 10D show a schematic method thereof.

The electronic part 2 has been fixed beforehand onto a mounting substrate 3 by die-bonding or the like.

FIG. 10A shows an FAB (Free Air Ball: crimp ball) forming step. In this step, by discharging electricity from a torch 17 to the tip end portion of the Au wire 11 supported so as to be supplied by the capillary 13, a crimp ball 11A is formed at the tip end portion.

FIG. 10B shows a first bonding step. In this step, in a state in which the crimp ball 11A is pressed against the first electrode 21 on the electronic part 2 with a predetermined load by the capillary 13, ultrasonic waves are oscillated at a predetermined intensity and for a predetermined time period so that the crimp ball 11A and the first electrode 21 are formed into an alloy and are thus bonded.

FIG. 10C shows a loop forming step. In this step, by moving the capillary 13 while the wire 11 is supplied, the wire 11 is formed into a predetermined loop shape.

FIG. 10D shows a second bonding step. In this step, the wire 11 is pressed against the second electrode 31 of the mounting substrate 3 with a predetermined load by the capillary 13, and ultrasonic waves are oscillated at a predetermined intensity and for a predetermined time period, so that they are bonded.

After bonding, the capillary 13 rises. After the wire 11 is cut at a set length, the capillary 13 moves to the next bonding position.

As described above, the wire bonding method is performed while a cycle, which includes the steps shown in FIGS. 10A to 10D, is being repeated. The necessary time period of one cycle is approximately 0.15 s. The details of each step will be described below.

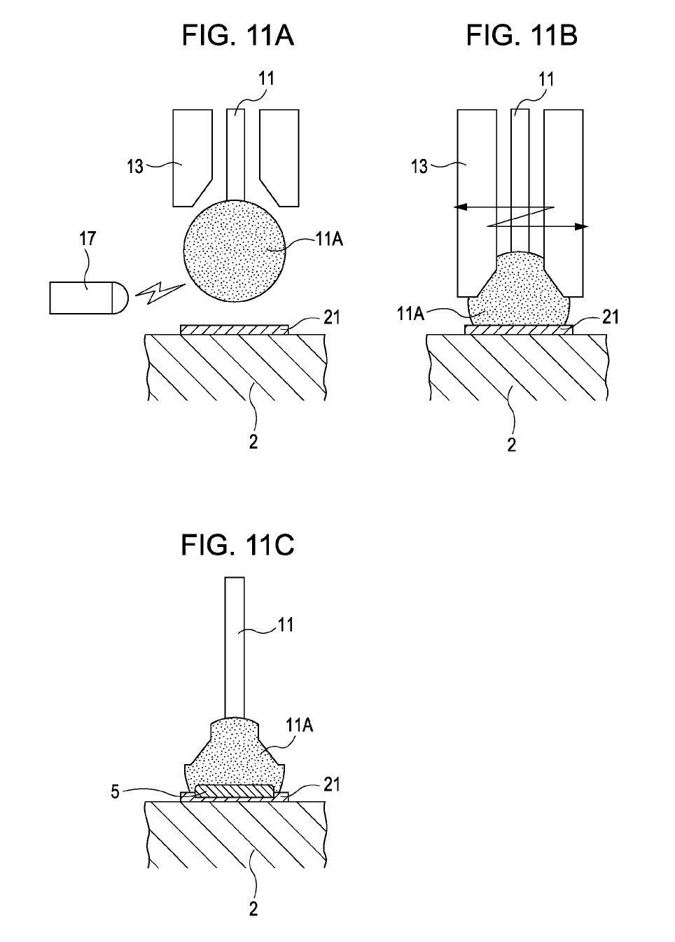

FIGS. 11A to 11C show the details of the FAB forming step and the first bonding step. As shown in FIG. 11A, by discharging electricity from the torch 17 to the tip end portion of the wire 11 protruding a predetermined length from the capillary 13, an FAB (crimp ball) 11A is formed at the tip end portion. In general, as the material forming the wire 11, Au (gold) having a purity of 99% or higher is used.

Next, as shown in FIG. 11B, the formed crimp ball 11A is pressed against the first electrode 21 formed from Al by the capillary 13, and is vibrated using ultrasonic waves while a predetermined load is applied. The ultrasonic waves are oscillated in the vibrator 16, causing the capillary 13 to be vibrated via the ultrasonic wave horn 14. At this time, the vibration time period using ultrasonic waves is approximately 10 ms.

As a result, as shown in FIG. 11C, an Au/Al alloy layer 5 is formed, and the wire 11 (crimp ball 11A) and the first electrode 21 are bonded together.

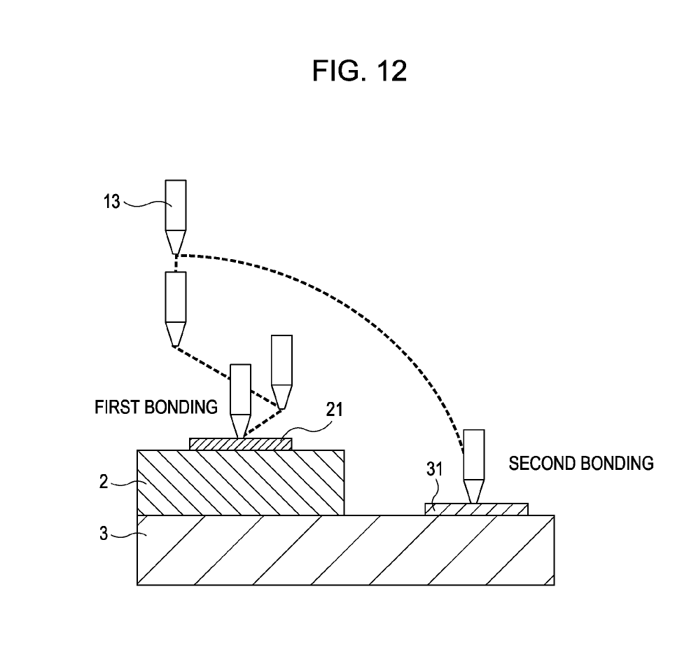

FIG. 12 shows the details of the loop forming step. The dashed line in the figure indicates an example of the movement locus of the capillary 13. After the first bonding step is performed, the capillary 13 is moved on the basis of the set loop shape, a deformation is given to the wire 11 supplied from the tip end of the capillary 13, thereby forming a predetermined loop shape. Thereafter, the second bonding step is performed.

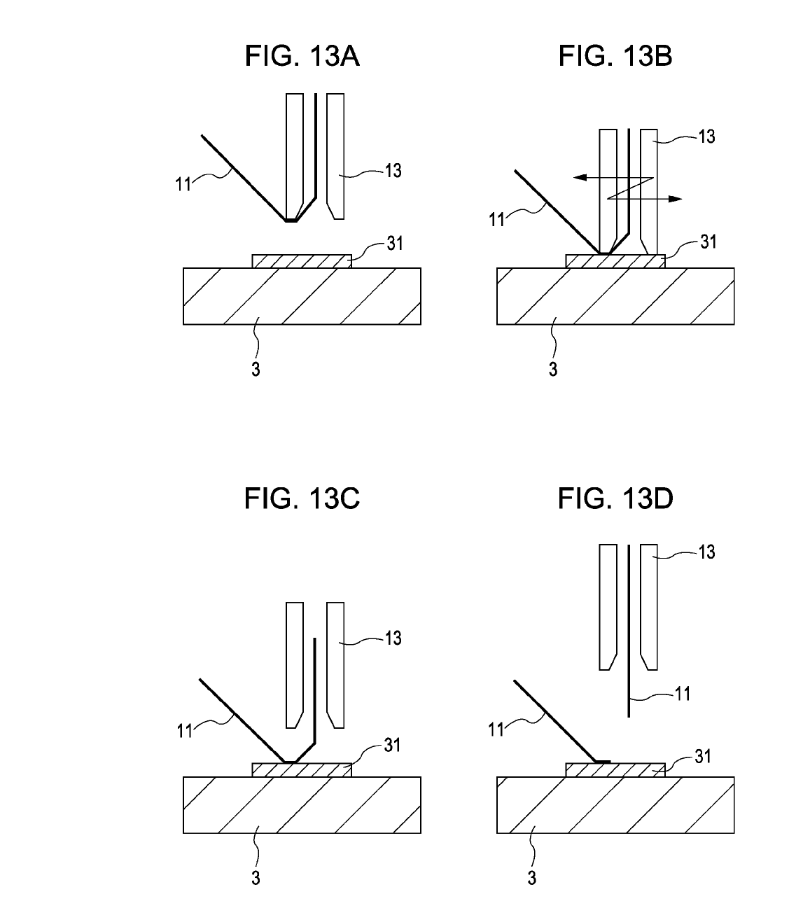

FIGS. 13A to 13D show the details of the second bonding step. FIG. 13A shows a status in which the wire 11 is formed in a predetermined loop shape above the second electrode 31 of the mounting substrate 3. From this status, as shown in FIG. 13B, the capillary 13 causes the wire 11 to be brought into abutment with the second electrode 31 on the mounting substrate 3 with a predetermined load, and these are vibrated using ultrasonic waves. As a result, the wire 11 and the second electrode 31 are bonded by performing metallic bonding in the abutment area. Thereafter, the capillary 13 is made to rise to a predetermined height (see FIG. 13C), and the wire 11 is cut (see FIG. 13D). Thus, the second bonding step is completed.

The wire bonding method shown in the above-described example enables metallic (electrical) bonding using the wire 11 to be performed between the first electrode 21 of the electronic part 2 and the second electrode 31 of the mounting substrate 3.

However, in the wire bonding method of the related art, usually, since Au having a high purity (purity 99% or higher) is used for the wire 11, a problem arises in that the Au/Al alloy layer 5 between the crimp ball 11A and the first electrode (Al pad) 21, which are formed in the first bonding step, grow over time.

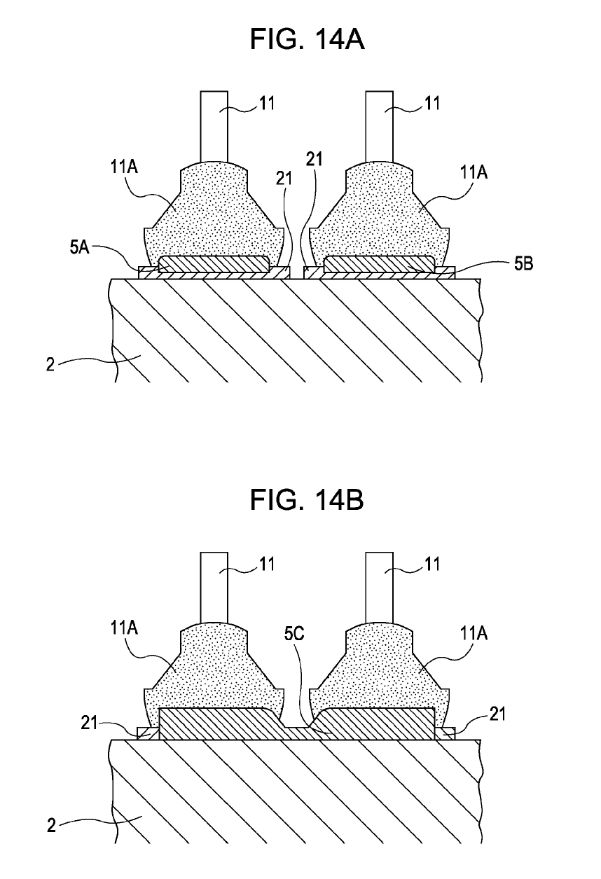

In more detail, as shown in FIG. 14A, between portions where the adjacent crimp ball 11A and the first electrode (Al pad) 21 are bonded, the Au/Al alloy layers 5 (reference numerals 5A and 5B in FIG. 14A) grow as time passes and contact each other (reference numeral 5C in FIG. 14B), and a short-circuit occurs between the adjacent bonded portions, causing the electronic apparatus to malfunction. Furthermore, regarding this phenomenon, the higher the temperature of the environment, the higher the rate of growth of the Au/Al alloy layers 5, causing a defect (short-circuit) to occur in a short time period.

As an example, the first electrode 21 is in the shape of a rectangle, one side of which is approximately 45 μm, and the distance between the adjacent bonded areas (between the first electrodes 21) is approximately 5 μm.

Furthermore, the Au/Al alloy layer 5 causes Kirkendall voids to be generated. Kirkendall voids are voids that are formed on the basis of the difference in the mutual diffusion speeds of different kinds of metal atoms in contact, and may cause bonded portions to peel off as time passes. That is, this phenomenon is one of the factors that cause poor conduction of the electronic apparatus.

Therefore, in vehicle-installed electronic apparatuses or medical electronic apparatuses necessitating high reliability, developing countermeasures for preventing malfunction of an electronic apparatus has been a challenge.

Next, a description will be given below of a wire bonding method according to an embodiment.

As an example, a description will be given of a case in which the wire bonding method according to the present embodiment is performed by using the wire bonding apparatus 1, the electronic part (IC chip) 2, and the mounting substrate 3, which are described in the above-described wire bonding method. A description will be given starting with a state in which the electronic part 2 has been die-bonded onto the mounting substrate 3.

As shown in FIG. 3A, a bump 22 is formed on the first electrode 21 of the electronic part 2.

Here, as a feature of the present embodiment, materials containing Au are used for the material forming the bump 22 and the material forming the wire 11 and also, the materials are determined so that the Au purity of the material forming the bump 22 is lower than the Au purity of the material forming the wire.

More specifically, it is preferable that the Au purity of the material forming the wire 11 be higher than or equal to 99% and lower than or equal to 100% and the Au purity of the material forming the bump 22 be from 75% to less than 99%. As an example, in the present embodiment, for the material forming the wire 11, a material having an Au purity of 99.99% is used, and for the material forming the bump 22, an alloy material having a Au purity of 80% and containing 20% of Ag as the other constituent element is used. Examples of the material other than Au, which forms the alloy material, include Ag and Pd. The shape of the crimp ball 11A can be made to be a spherical shape suitable for bonding, and no variations occur in the shape, which is preferable.

Furthermore, as the structure that is characteristic of the present embodiment, for the method of forming the bump 22, a method is adopted in which a ball (crimp ball) formed by discharging electricity to the tip end portion of the material (bump forming wire) containing Au in the shape of a wire, which is provided separately from the connection wire 11, is brought into abutment with the first electrode 21, and ultrasonic wave vibration is applied while a predetermined load is applied, thereby forming the bump 22.

In more detail, the same method as the method described with reference to FIGS. 10A and 10B in the wire bonding method of the related art enables the bump 22 to be formed. That is, similarly to the FAB forming step of FIG. 10A, by discharging electricity from the torch 17 to the tip end portion of the wire (bump forming wire) that is supported so as to be suppliable by the capillary 13, a crimp ball is formed at the tip end portion of the wire (bump forming wire).

Next, similarly to the first bonding step of FIG. 10B, in a state in which the crimp ball is pressed against the first electrode 21 on the electronic apparatus 2 with a predetermined load by the capillary 13, ultrasonic wave vibration is performed at a predetermined intensity and for a predetermined time period, and the crimp ball and the first electrode 21 are formed into an alloy and are thus bonded.

Next, by cutting the wire (bump forming wire) after bonding, the bump 22 is formed on the first electrode 21, as shown in FIG. 3A.

According to the method of forming the bump 22, both of the formation of the wire 11 and the formation of the bump 22 can be performed by only changing the type of wire by using the same apparatus as the wire bonding apparatus 1. Thus, since it is not necessary to provide no special processing apparatuses and steps, great advantages are obtained in terms of the manufacturing process.

Of course, the bump 22 may be formed on the first electrode 21 by employing another method.

Next, as a step following FIG. 3A, as shown in FIG. 3B, a first bonding step is performed onto the bump 22 by using the wire 11. Thereafter, after undergoing, as shown in FIG. 3C, a loop forming step, as shown in FIG. 3D, a second bonding step is performed onto the second electrode 31 on the substrate. Thereafter, the wire 11 is cut at a predetermined position. As described above, for the wire 11, a material having an Au purity higher than that of the material forming the bump 22 is used.

The method of performing these steps is the same as the method performed with reference to FIGS. 10B to 10D (detailed views) above, and accordingly, descriptions thereof are omitted.

After undergoing the steps shown as an example in the foregoing, the electronic apparatus 4 having the configuration shown in FIG. 4 according to the present embodiment is formed.

Here, FIGS. 5A and 5B show schematic sectional views of a bonded area in the first bonding step. FIG. 5A shows the case of a wire bonding method according to the present embodiment. FIG. 5B shows the case of a wire bonding method of the related art. In the first bonding step, in the related art, the wire 11 (crimp ball 11A) is directly bonded to the first electrode 21. As a result, the Au (high purity)/Al alloy layer 5 that allows for the above-described problem to occur is formed in the bonded area.

In comparison, in the present embodiment, a bump 22 is formed using a wire (bump forming wire) having a low Au purity on the first electrode 21, and bonding is performed on the bump 22 by using the wire 11 having a high Au purity. As a result, although an Au (low purity)/Al alloy layer 6 is formed in the area where the bump 22 and the first electrode 21 are bonded, it is possible to solve the problem that has been the problem in the Au (high purity)/Al alloy layer 5 of the related art.

More specifically, as shown in the correlation diagram of FIG. 6 between the high-temperature left-standing time period and the alloy layer diameter of the bonded area, the result in the case of the Au (high purity)/Al alloy layer 5 of FIG. 5B (indicated by data having a Au purity of 99.99% in FIG. 6) reveals that, if left to stand in a high-temperature environment, the alloy layer grows as time passes. However, in the case of the Au (low purity)/Al alloy layer 6 of FIG. 5A (indicated by data having an Au purity of 80% in FIG. 6), an advantage that alloy layer growth over time is suppressed in a high-temperature environment is obtained.

In the bonded area of the wire 11 (crimp ball 11A) and the bump 22 in the present embodiment, since both are materials containing Au, the problem of the Au/Al alloy layer does not occur.

On the basis of this result, according to the configuration of the present embodiment, it is possible to solve the problem of a short-circuit between adjacent bonded portions, which results from alloy layer growth in the bonded portions in the first bonding step, which has been a problem in the related art.

Regarding this point, if the problem of the alloy layer growth in the bonded portions of the first bonding is to be solved, in the wire bonding method of the related art, it is considered that the growth of the alloy layer can also be suppressed by using an Au wire having a low purity (for example, purity 80%) for the connection wire 11. However, an Au wire having a low purity (for example, purity 80%) has an electrical resistance which is approximately four times higher than that of an Au wire having a high purity (for example, purity 99.99%). As a consequence, applications to, in particular, electronic apparatuses that have been increasingly downsized pose large limitations in design because measures have to be taken for formation of shorter wires, thicker wires, and the like, and these measures present the problem of obstructing practical applications.

With respect to this problem, according to the wire bonding method in accordance with the present embodiment, an Au wire having a high purity (for example, purity 99.99%) can be used as the connection wire 11. As a result, the problem of an alloy layer short-circuit between adjacent crimp balls, which results from alloy layer growth, is solved and also, the problem in an increase in the resistance value of the wire due to the use of a low-purity wire can be solved at the same time.

Next, another embodiment of the electronic apparatus to be manufactured will be described.

The electronic apparatus 4 shown in FIG. 7 is manufactured in the step procedure described with reference to FIGS. 3A to 3D similarly to the electronic apparatus 4 shown in FIG. 4 (front sectional view). The electronic apparatus 4 is an example in the case that the second electrode 31 on the mounting substrate 3 is provided at a position higher than the bump 22 formed on the first electrode 21 of the electronic part 2.

The electronic apparatus 4 shown in FIG. 8 is an example in the case that it is manufactured in the step procedure of so-called reverse bonding. More specifically, after the step shown in FIG. 3A, that is, the step of forming the bump 22 on the first electrode 21 of the electronic part 2, is performed, the wire 11 (crimp ball 11A) and the second electrode 31 on the mounting substrate 3 are bonded (the first bonding step in the reverse bonding). Thereafter, the electronic apparatus 4 is manufactured in the procedure in which the wire 11 and the bump 22 are bonded (the second bonding step in the reverse bonding).

That is, whereas the bonding position of the crimp ball 11A is on the bump 22 in the electronic apparatus 4 of FIG. 4, in the electronic apparatus 4 according to the present embodiment, the bonding position is on the second electrode 31. The materials forming the component members are the same as in the case described with reference to FIGS. 3A to 3D, and descriptions thereof are omitted herein.

The electronic apparatus 4 shown in FIG. 9 is an example in the case that, similarly to the electronic apparatus 4 shown in FIG. 8, it is manufactured in the step procedure of reverse bonding and also in the case that, similarly to the electronic apparatus 4 shown in FIG. 7, the second electrode 31 on the mounting substrate 3 is provided at a position higher than the bump 22 formed on the first electrode 21 of the electronic part 2.

As has been described above, according to the wire bonding method according to the present embodiment, the following problems can be simultaneously solved: a problem of a short-circuit between adjacent bonded areas and the peeling off of the bonded area, which result from growth over time of Au/Al alloy layers formed at the bonded area between a high-purity Au wire and a metal (Al) pad, which are the above-described problems, and another problem that, regarding applications to electronic apparatuses that have been increasingly downsized, use of a low-purity Au wire capable of suppressing the growth of Au/Al alloy layers poses large limitations in design in terms of formation of shorter wires, formation of thicker wires, and the like.

As a result, according to the electronic apparatus manufactured by the wire bonding method according to the present embodiment and the method of manufacturing the electronic apparatus, it is possible to suppress occurrence of a short-circuit and peeling off in the bonded area by wire bonding. In an electronic apparatus used, in particular, in a high-temperature environment, it is possible to ensure a high reliability.

A description has been given using as an example an electronic apparatus employing wire bonding connection. It is of course possible to apply the technical concept to electronic apparatuses employing flip-chip connection, and the like.

The embodiment described above is a preferred embodiment. The present invention is not limited to this but various modifications can be made without departing from the spirit of the present invention.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions has been described in detail, it should be understood that various changes, substitutions, and alterations could be made hereto without departing from the spirit and scope of the invention.

What is claimed is:

1. A wire bonding method comprising the steps of:
forming a bump on a first electrode provided in a first electronic part; and
bonding the bump and a second electrode provided in a second electronic part by using a wire,
wherein the bump and the wire are formed using materials containing Au, and an Au purity of the material forming the bump is lower than an Au purity of the material forming the wire.

2. A method of manufacturing an electronic apparatus, comprising the steps of:
forming a bump on a first electrode provided in an electronic part; and
bonding the bump and a second electrode provided on a mounting substrate by using a wire,
wherein the bump and the wire are formed using materials containing Au, and an Au purity of the material forming the bump is lower than an Au purity of the material forming the wire.

3. The method of manufacturing an electronic apparatus according to claim 2, wherein the Au purity of the material forming the bump is higher than or equal to 75% and lower than 99%, and the Au purity of the material forming the wire is higher than or equal to 99% and lower than or equal to 100%.

4. The method of manufacturing an electronic apparatus according claim 2, wherein the step of forming the bump further includes a step of forming the bump by bringing a ball formed by discharging electricity to a tip end portion of a material containing Au in the shape of a wire into abutment with the first electrode and by performing ultrasonic wave vibration while a load is applied.

5. The method of manufacturing an electronic apparatus according claim 3, wherein the step of forming the bump further includes a step of forming the bump by bringing a ball formed by discharging electricity to a tip end portion of a material containing Au in the shape of a wire into abutment with the first electrode and by performing ultrasonic wave vibration while a load is applied.

6. The method of manufacturing an electronic apparatus according to claim 2, wherein the material containing Au, which forms the bump, contains at least one of Ag and Pd.

7. An electronic apparatus comprising:
a bump provided on a first electrode of an electronic part; and
a wire that bonds the bump to a second electrode provided on a mounting substrate,
wherein the second electrode and the bump are formed using materials containing Au, and an Au purity of the material forming the bump is lower than an Au purity of the material forming the second electrode.
